(19) United States
(12) Patent Application Publication
(10) Pub. No.: US 2007/0296008 A1
(43) Pub. Date: Dec. 27, 2007

(54) SEMICONDUCTOR DEVICE

(75) Inventor: Eiji NATORI, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/758,719

(22) Filed: Jun. 6, 2007

(30) Foreign Application Priority Data
Jun. 9, 2006 (JP) 2006-161064

(51) Int. Cl. H01L 29/94

(52) U.S. Cl. 257/295

(57) ABSTRACT

A semiconductor device includes: a semiconductor substrate; a transistor formed on the semiconductor substrate; an interlayer dielectric layer that covers the transistor; a ferroelectric capacitor formed above the interlayer dielectric layer and having a first electrode, a ferroelectric layer and a second electrode; another interlayer dielectric layer that covers the ferroelectric capacitor and is different from the interlayer dielectric layer; and a sensor that is formed above the semiconductor substrate and is one of a pressure sensor, a pyroelectric sensor and a magnetic sensor.

The entire disclosure of Japanese Patent Application No. 2006-161064, filed Jun. 9, 2006 is expressly incorporated by reference herein.

### BACKGROUND

1. Technical Field

The present invention relates to a semiconductor device in which a FeRAM (Ferroelectric Random Access Memory) and a sensor are mixed and mounted together.

2. Related Art

As nonvolatile memories that keep storing information even after the power is turned off, flash memory, EPPROM and FeRAM are known. Above all, FeRAM is capable of high-speed writing and operation with low power consumption, compared to the other nonvolatile memories, such that its application is expected in a wide range of industrial fields, such as, the field of portable equipment, the field of automobile electronic equipment, the field of robots and the like. On the other hand, among various systems of sensors, MEMS (Micro Electro Mechanical Systems) have been attracting attention in recent years. With the MEMS technology, mass production can be readily achieved as it can make the best use of the semiconductor manufacturing technology, and therefore applications of the MEMS technology to gyro stabilizers for automobiles, acceleration sensors for camera image stabilization, pressure sensors and the like have been promoted. Japanese laid-open patent application JP-A-2005-249395 is an example of related art.

### SUMMARY

In accordance with an aspect of the present invention, there is provided a novel semiconductor device in which a FeRAM and a specific sensor are mixed and mounted together.

A semiconductor device in accordance with an embodiment of the invention includes: a semiconductor substrate; a transistor formed on the semiconductor substrate; an interlayer dielectric layer that covers the transistor; a ferroelectric capacitor formed above the interlayer dielectric layer and having a first electrode, a ferroelectric layer and a second electrode; another interlayer dielectric layer that covers the ferroelectric capacitor and is different from the interlayer dielectric layer; and a sensor that is formed above the semiconductor substrate and is one of a pressure sensor, a pyroelectric sensor and a magnetic sensor.

According to the semiconductor device in accordance with the present embodiment, the sensor and the ferroelectric memory (FeRAM) that is capable of high-speed writing operation are mixed and mounted together, and therefore a weak signal from the sensor can be processed, and data can be stored instantaneously even when the power supply is cut. For this reason, the semiconductor device in accordance with the present embodiment is applicable to a wide range of usages.

In the semiconductor device in accordance with the present embodiment, the sensor may be formed above the other interlayer dielectric layer.

In the semiconductor device in accordance with the present embodiment, the sensor may be formed on the semiconductor substrate.

In the semiconductor device in accordance with the present embodiment, the ferroelectric capacitor and the sensor may have layers composed of identical types of complex oxides.

In the semiconductor device in accordance with the present embodiment, the ferroelectric layer of the ferroelectric capacitor may be composed of a complex oxide expressed by Pb(Zr, Ti)₁₋ₓNbₓO₃.

In the semiconductor device in accordance with the present embodiment, in the complex oxide of the ferroelectric layer, x may be in a range of 0.05≦x≦0.3.

In the semiconductor device in accordance with the present embodiment, the complex oxide may include Si, or Si and Ge in 0.5 mol % or more.

In the semiconductor device in accordance with the present embodiment, the sensor may be a pressure sensor, and the pressure sensor may have a ferroelectric layer.

In the semiconductor device in accordance with the present embodiment, the sensor may be a pyroelectric sensor, and the pyroelectric sensor may have a ferroelectric layer.

In the semiconductor device in accordance with the present embodiment, the ferroelectric layer may be composed of a complex oxide expressed by Pb(Zr, Ti)₁₋ₓNbₓO₃.

### BRIEF DESCRIPTION OF THE DRAWINGS

FIG. 1 is a cross-sectional view schematically showing a semiconductor device having a pressure sensor in accordance with an embodiment of the invention.

FIG. 2 is a plane view schematically showing a pressure sensor.

FIG. 3 is a cross-sectional view of the pressure sensor shown in FIG. 2 taken along a line A-A.

FIGS. 4A through 4D are perspective views schematically showing a method for manufacturing the pressure sensor shown in FIG. 2.

FIG. 5 is a partially broken perspective view of a pyroelectric sensor.

FIG. 6 is a plan view schematically showing a magnetic sensor.

FIGS. 7A through 7C are cross-sectional views showing a method for manufacturing the magnetic sensor shown in FIG. 6.

FIG. 8 is a graph showing Raman vibration spectra of PZTN.

### DESCRIPTION OF EXEMPLARY EMBODIMENTS

Preferred embodiments of the present invention are described below with reference to the accompanying drawings.

### 1. First Embodiment

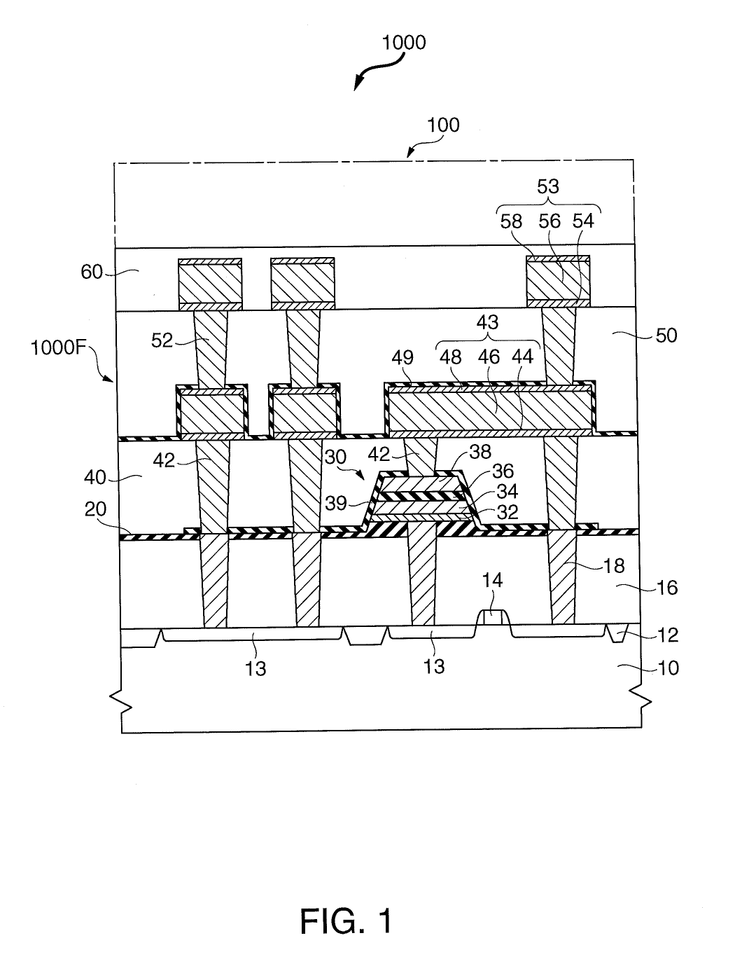

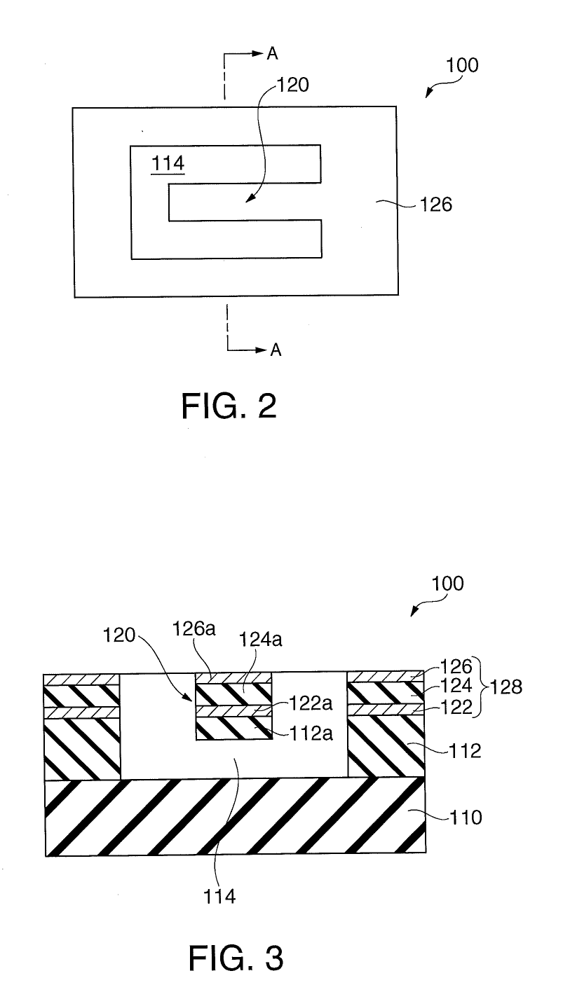

1.1. FIG. 1 is a cross-sectional view schematically showing a semiconductor device 1000 having a pressure sensor 100 mixed and mounted therein as a sensor, FIG. 2 is a plane view schematically showing a main part of the pressure sensor 100, and FIG. 3 is a schematic cross-sectional view of a section taken along a line A-A of FIG. 2. In the illustrated example, the pressure sensor 100 is formed at the uppermost layer of the semiconductor device 100.

First, a memory section 1000F composing a FeRAM is described.

The memory section 1000F that composes a FeRAM includes a MOS transistor 14 and a ferroelectric capacitor 30. In the illustrated example, an element isolation region 12 is formed in a semiconductor substrate (e.g., a silicon substrate) 10. The MOS transistor 14 is formed in a region that is defined by the element isolation region 12. Regions 13 are impurity regions that form source/drain regions of the MOS transistor 14 or contact regions. The MOS transistor 14 is covered by a first interlayer dielectric layer 16. The first interlayer dielectric layer 16 has a plurality of first contact sections 18 formed at specified positions. The first contact sections 18 are so-called plugs, and may be composed of a high melting-point metal such as tungsten, molybdenum and tantalum.

The ferroelectric capacitor 30 is formed above the first interlayer dielectric layer 16 through a first barrier layer 20. More specifically, a barrier layer 32 is formed on the first interlayer dielectric layer 16. The first barrier layer 20 and the second barrier layer 32 are formed on the first contact section (plug) 18 having at least a portion connected to the ferroelectric capacitor 30. The second barrier layer 32 is provided to prevent oxidation of the first contact section 18.

The first barrier layer 20 may be composed of any material that has dielectric property and hydrogen barrier capability without any particular limitation. As the material of the first barrier layer 20, a film of alumina, silicon nitride or the like can be enumerated.

The second barrier layer 32 may be composed of any material that has conductivity and oxygen barrier capability without any particular limitation. As the material of the second barrier layer 32, for example, TiAlN, TiAl, TiSiN, TiN, TaN, and TaSiN may be enumerated. Above all, a layer that includes titanium, aluminum and nitrogen (TiAlN) would be more favorable.

The ferroelectric capacitor 30 having a first electrode (lower electrode) 34, a ferroelectric layer 36 and a second electrode (upper electrode) 38 is formed on the second barrier layer 32.

The first electrode 34 may be composed of at least one type of material selected from platinum, ruthenium, rhodium, palladium, osmium and iridium. The third electrode 34 may preferably be composed of platinum or iridium, and more preferably iridium. The first electrode 34 may be formed from a single layer film or a multilayer film of laminated layers.

The ferroelectric film 36 is composed of complex oxide. The complex oxide may have a perovskite crystal structure. As the complex oxide, Pb(Ti, ZrO₃)(PZT) is a typical material, and a small amount of additive element may be added to this basic structure. Also, as the complex oxide, SrBi₂Ta₂O₉ (SBT) and (Bi, La)₄Ti₃O₁₂(BLT) having a crystal structure originated from a perovskite type crystal structure may be used.

As the material of the ferroelectric layer 36, PZT is favorable, and in this case, the first electrode 34 may preferably be composed of iridium from the viewpoint of device reliability. Also, when PZT is used as the material of the ferroelectric layer 36, the content of titanium in the PZT may preferably be greater than the content of zirconium in order to obtain a greater amount of spontaneous polarization.

Moreover, the ferroelectric layer 36 may be composed of a complex oxide that is expressed by Pb(Zr, Ti)₁₋ₓNbₓO₃ (PZTN). This aspect is described below in detail.

The second electrode 38 may be composed of any of the materials described above as an example of the material that can be used as the first electrode 34, or may be composed of aluminum, silver, nickel or the like. Also, the second electrode 38 may be in a single layer film, or a multilayer film of laminated layers. The second electrode 38 may preferably be composed of platinum, or a laminated film of layers of iridium oxide and iridium.

Also, in the semiconductor device 100 in accordance with the present embodiment, as shown in FIG. 1, a third barrier layer 39 that covers the side surface and the upper surface of the ferroelectric capacitor 30 is provided. The third barrier layer 39 may preferably be composed of a material having a hydrogen barrier capability to prevent reduction of the ferroelectric layer 36. In other words, the third barrier layer 39 has a function to prevent the ferroelectric layer 36 that is composed of oxide from being reduced and deteriorated by the semiconductor processing that is based on hydrogen processing. The third barrier layer 39 may be composed of, for example, alumina or p-TEOS.

Next, PZTN that is favorable as the material of the ferroelectric layer 36 is described.

The ferroelectric layer 36 may be composed of Pb(Zr, Ti)₁₋ₓNbₓO₃ (PZTN) in which Nb is doped in the Ti site. In this case, Nb can be contained in a range of 0.1≦x≦0.3. Also, the ratio of Zr to Ti (Zr/Ti) may be 0.2-0.5. The composition ratio (mol ratio) of PZTN composing the ferroelectric layer 36 may be, for example, Pb/Zr/Ti/Nb=115/40/40/20.

The ferroelectric layer 36 is described below in detail.

Because Nb has generally the same size as that of Ti (ionic radii are close to each other and atomic radii are identical), and weighs two times, it is hard for atoms to slip out the lattice even by collision among atoms by lattice vibration. Further, its valence is +5, which is stable. Therefore, even if Pb slips out, the valence resulting from the vacated Pb can be compensated by Nb⁵⁺. Also, even if a Pb vacancy occurs at the time of crystallization, it is easier for Nb having a smaller size to enter than 0 having a larger size to slip out.

Furthermore, Nb may also have a valence of +4, such that it can sufficiently substitute for Ti⁴⁺. Moreover, Nb has in effect a very strong covalent bond, and it is believed that Pb is also difficult to slip out (H. Miyazawa, E. Natori, S. Miyashita; Jpn. J. Appl. Phys. 39 (2000) 5679).

Because the ferroelectric layer 36 is composed of PZTN, and the PZTN contains Nb in a specific proportion, adverse effects by the Pb vacancy are canceled, and excellent composition controllability can be obtained. As a result, the PZTN has excellent hysteresis characteristics, leakage characteristics, reduction resistance and insulating property, compared to an ordinary PZT.

Until now, the Nb doping in PZT has been mainly performed into Zr-rich rhombohedral crystal regions and is extremely small, on the order of 0.2 to 0.025 mol % (see J. Am. Ceram. Soc, 84 (2001) 902 and Phys. Rev. Let, 83 (1999) 1347). The main reason why it has not been possible to dope a large amount of Nb is considered to be because the addition of 10 mol % of Nb, for example, would cause the crystallization temperature to elevate to 800° C. or higher.

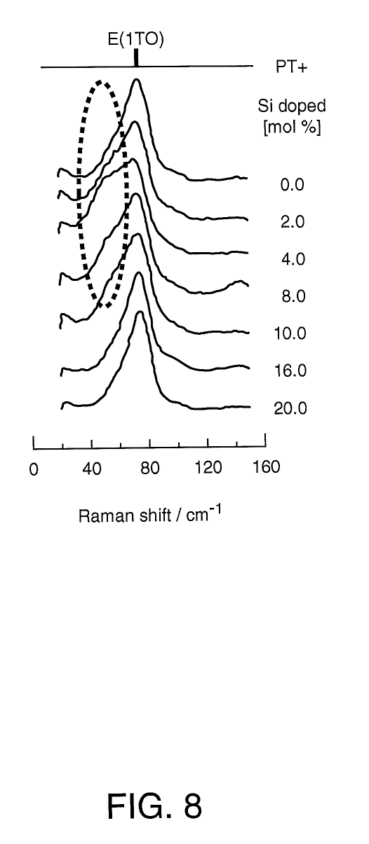

Therefore, PbSiO₃ silicate may preferably be further added by a proportion of 0.5-10 mol %, for example, in the precursor composition for forming the ferroelectric layer 36. This makes it possible to reduce the crystallization energy of the PZTN. In other words, if PZTN is used as the material of the ferroelectric layer, the addition of PbSiO₃ silicate together with addition of Nb makes it possible to reduce the crystallization temperature of the PZTN. Also, instead of silicate, a mixture of silicate and germanate may be used. The inventors of the present application confirmed that silicon composed a part of the crystal as the A site ion, after it functioned as a sintering agent (see FIG. 8). In other words, as shown in FIG. 8, when silicon was added in lead titanate, changes were observed in the Raman vibration mode E (1TO) of A site ions. Also, changes were observed in the Raman vibration mode, when the amount of Si added was 8 mol % or less. Accordingly, it was confirmed that Si existed at the A site of perovskite when a small amount of Si was added.

As described above, in accordance with the present embodiment, the ferroelectric material expressed by Pb(Zr, Ti, Nb) O₃ (PZTN) may preferably include Si, or Si and Ge by 0.5 mol % or more, and more preferably include Si, or Si and Ge by 0.5 mol % or more but less than 10 mol %.

Furthermore, a second interlayer dielectric layer 40 is formed on the third barrier layer 39. Second contact sections 42 are formed in the second interlayer dielectric layer 40 at specified locations. Each of the second contact sections 42 penetrates the third barrier layer 39 and is connected to the first contact section 18. The second contact sections 42 may be composed of a material similar to that of the first contact layers 18. The second electrode 38 of the ferroelectric capacitor 30 is connected to one of the second contact sections 42.

A first wiring layer 43 is formed on the second interlayer dielectric layer 40. The first wiring layer 43 includes a lower electrode barrier layer 44, a conductive layer 46 and an upper electrode barrier layer 48. As the material of the conductive layer 46, aluminum, copper, ruthenium, iridium or platinum may be used. When the process temperature for forming a sensor 100 to be described below is high, copper, ruthenium, iridium or platinum may preferably be used. Furthermore, a fourth barrier layer 49 is formed on the first wiring layer 43. The fourth barrier layer 49 is a hydrogen barrier layer, and may be composed of, for example, alumina. The fourth barrier layer 49 has a function similar to that of the third barrier layer 39 formed on the surface of the ferroelectric capacitor 30.

The first wiring layer 43 is covered by a third interlayer dielectric layer 50. Third contact sections 52 are formed in the third interlayer dielectric layer 50 at specified positions. The second electrode 38 of the ferroelectric capacitor 30 and the first wiring layer 40 are connected to each other by the second contact section 42.

Second wiring layers 53 are formed on the third interlayer dielectric layer 50. The second wiring layer 53 includes a lower electrode barrier layer 54, a conductive layer 56 and an upper electrode barrier layer 58, like the first wiring layer 43. As the material of the conductive layer 56, a material similar to that of the conductive layer 46 of the first wiring layer 43 may be used. The second wiring layer 53 is covered by a fourth interlayer dielectric layer 60.

The layer structure of the memory section 1000F composing the FeRAM described above is an example, and the number of layers of the wiring layer can be appropriately selected.

Next, the pressure sensor 100 is described.

In accordance with the present embodiment, the sensor 100 is formed at the uppermost layer (on the fourth interlayer dielectric layer 60), as shown in FIG. 1. The pressure sensor 100 is to obtain an electrical output corresponding to an input of a mechanical rate (such as, pressure and acceleration), and includes an acceleration sensor and an ultrasonic sensor. Although not shown in the figure, the pressure sensors 100 may be arranged in a plurality of rows, which may be formed in an array.

FIG. 2 is a plane view showing an example of the pressure sensor 100, and FIG. 3 is a cross-sectional view taken along a line A-A shown in FIG. 2.

The pressure sensor 100 includes a first dielectric layer 110 formed on the fourth interlayer dielectric layer 60 of the memory section 1000F shown in FIG. 1, and a second dielectric layer 112 formed on the first dielectric layer 110. A piezoelectric laminate section 128 in which a first electrode layer 122, a piezoelectric layer 124 and a second electrode layer 126 are laminated is formed on the second dielectric layer 112. A cavity 114 is formed in the piezoelectric laminate section 128 and the second dielectric layer 112. The cavity 114 is provided with a cantilever-like oscillator 120.

The oscillator 120 includes a first electrode layer 122a, a piezoelectric layer 124a and a second electrode layer 126a composing the piezoelectric laminate section 128. In the illustrated example, a second dielectric layer 112a composing a part of the second dielectric layer 112 is formed below the first electrode layer 122a. As the oscillator 120 has the second dielectric layer 112a, its mechanical strength is further enhanced. The length, width and thickness of the oscillator 120 may be adjusted whereby the magnitude of a pressure to be detected can be controlled.

As the material of the first dielectric layer 110, for example, alumina may be used. As the material of the second dielectric layer 122, for example, silicon oxide may be used. The first electrode layer 122 may be formed from a metal such as ruthenium, iridium and platinum, or a conductive oxide such as iridium oxide. As the material of the piezoelectric layer 124, a complex oxide similar to that of the ferroelectric layer 36 of the ferroelectric capacitor 30 may preferably be used without any particular limitation. For example, when PZTN is used as the ferroelectric layer 36, PZTN may also be used as the piezoelectric layer 124. However, the ratio between zirconium (Zr), titanium (Ti) and niobium (Nb) shall be appropriately selected in consideration of the characteristics of the ferroelectric or piezoelectric material. The composition ratio (mol ratio) of PZTN composing the piezoelectric layer 124 may be, for example, Pb/Zr/Ti/Nb=115/55/25/20. In other words, the piezoelectric layer 124 would become so-called zirconium-rich in which the rate of zirconium is greater than the rate of titanium, compared to the ferroelectric layer 36.

Although not shown in the figure, the pressure sensor 100 and the wiring layer of the memory section 1000F and devices such as the MOS transistor which compose the FeRAM are connected to one another through the contact sections.

According to the semiconductor device 1000 described above, the pressure sensor 100 is formed in a manner being laminated above an area where the ferroelectric capacitor 30 is formed, such that the pressure sensor 100 and the ferroelectric capacitor 30 can be formed compactly in a specified region. As a result, the routing distance of the wiring can be made shorter, compared to the case where the pressure sensor is not laminated, such that a signal from the pressure sensor 100 can be effectively stored in the ferroelectric capacitor 30. The longer the routing length of the wiring becomes, the greater noises become. Therefore, in order to securely pick up a weak signal from the pressure sensor 100, a certain measure to amplify the signal near the pressure sensor or the like may need to be provided. However, in accordance with the present embodiment, because the pressure sensor 100 and the ferroelectric capacitor 30 composing the FeRAM can be formed close to each other, such an amplification device is not required, and a simpler circuit structure can be used.

Also, by forming the ferroelectric layer 36 of the ferroelectric capacitor 30 and the piezoelectric layer 124 of the pressure sensor 100 with the same kind of complex oxide, the process efficiency is improved.

The pressure sensor 100 shown in FIG. 2 and FIG. 3 is an example of pressure sensors, and may be in any one of known modes as a pressure sensor. Also, in the present embodiment, the pressure sensor 100 is formed above the memory section 1000F. However, the pressure sensor may also be formed above the semiconductor substrate 10 in an area different from the area where the memory section 1000F is formed. This similarly applies to the second and third embodiments to be described below.

1.2. Method for Manufacturing Semiconductor Device Having Pressure Sensor

(1) As shown in FIG. 1, first, an element isolation region 12 and a MOS transistor 14 are formed on a semiconductor substrate 10 by a known method. Then, a first interlayer dielectric layer 16 is formed by a known method. Next, first contact sections 18 are formed by a known method. For example, opening sections (contact holes) are formed in the interlayer dielectric layer 16 by dry etching, and then the opening sections are embedded with a conductive layer by a CVD method or a sputter method. Then, the upper surface of the first interlayer dielectric layer 16 is planarized by mechanical chemical polishing.

(2) A first barrier layer 20 is formed on the first interlayer dielectric layer 16. As the first barrier layer 20, a film of alumina or silicon nitride may be used. Then, a conductive second barrier layer 32 is formed. The barrier layers 20 and 30 may be formed by a known CVD method or a sputter method. Then, a laminate of a conductive layer for a first electrode 34, a complex oxide layer for a ferroelectric layer 36 and a conductive layer for a second electrode 38 for forming a ferroelectric capacitor 30 is formed. Then, by using known lithograph and dry etching methods, the laminate and the second barrier layer are patterned to thereby form the ferroelectric capacitor 30.

In the process described above, when PZTN is used as the ferroelectric layer 36, the following method may be applied.

The ferroelectric layer 36 composed of PZTN is formed by a solution method such as a sol-gel method, a MOD method or the like. In the present embodiment, the ferroelectric layer 36 may be formed by coating a specific precursor composition including precursor material for forming ferroelectric, and then heat treating the precursor material. The precursor composition and its manufacturing method are described in detail below.

The precursor composition includes at least one kind of a thermally decomposable organometallic compound including Pb, Zr, Ti or Nb, a hydrolysable organometallic compound including Pb, Zr, Ti or Nb, and its partial hydrolyzate and/or polycondensate, at least one kind of polycarboxylic acid and polycarboxylic acid ester, and an organic solvent.

The precursor composition can be formed by mixing organometallic compounds containing constituent metals of the material of the complex metal oxide or their partial hydrolyzate and/or polycondensate so that the metals are contained in a desired mole ratio, and further dissolving or dispersing them in an organic solvent such as alcohol. The organometallic compounds which are stable in a solution state may preferably be used.

The organometallic compounds that can be used in the present embodiment are selected from among alkoxides, organometallic complexes and organic acid salts of the metals, which can generate metal oxides originated from their metallo-organic compounds through hydrolysis or oxidation.

As the thermally decomposable organometallic compounds including constituent metals of the complex metal oxides, for example, organometallic compounds, such as, metal alkoxides, organic acid salts, and β diketone complexes may be used. As the hydrolysable organometallic compounds including constituent metals of the complex metal oxides, for example, organometallic compounds, such as, metal alkoxides may be used. As the organometallic compounds, the following organometallic compounds may be enumerated as examples.

As organometallic compounds containing Pb, lead acetate and lead octylate can be enumerated. As organometallic compounds containing Zr or Ti, alkoxides, acetates and octylate salts of Zr or Ti may be enumerated.

As organometallic compounds containing Nb, niobium octylate and lead niobium octylate may be enumerated. Niobium octylate has a structure in which two Nb atoms covalently bond together and octyl groups are present at other portions thereof.

As the organic solvent used in the raw material composition in accordance with the present embodiment, alcohol may be used. Both of organometallic compounds and polycarboxylic acid or polycarboxylic acid ester can be dissolved well in a solvent when alcohol is used as the solvent. Any alcohol can be used without any particular limitation, and monovalent alcohols such as buthanol, methanol, ethanol, propanol, and the like, and polyhydric alcohols can be enumerated. For example, the following can be enumerated as the alcohols.

Monovalent Alcohols:

As propanol (propyl alcohol), 1-propanol (97.4° C. in boiling point), and 2-propanol (82.7° C. in boiling point);

As buthanol (butyl alcohol), 1-buthanol (117° C. in boiling point), 2-buthanol (100° C. in boiling point), 2-methyl-1-propanol (108° C. in boiling point), and 2-methyl-2-propanol (25.4° C. in melting point and 83° C. in boiling point); and

As pentanol (amyl alcohol), 1-pentanol (137° C. in boiling point), 3-methyl-1-buthanol (131° C. in boiling point), 2-methyl-1-buthanol (128° C. in boiling point), 2,2-dimethyl-1-propanol (113° C. in boiling point), 2-pentanol (119° C. in boiling point), 3-methyl-2-buthanol (112.5° C. in boiling point), 3-pentanol (117° C. in boiling point), and 2-methyl-2-buthanol (102° C. in boiling point).

Polyhydric Alcohols:

Ethylene glycol (−11.5° C. in melting point, 197.5° C. in boiling point), and glycerin (17° C. in melting point, 290° C. in boiling point).

In the precursor composition, the polycarboxylic acid or the polycarboxylic acid ester may have a valence of 2 or more. The following can be enumerated as the polycarboxylic acids. As carboxylic acids with a valence of 3, trans-aconitic acid and trimesic acid can be enumerated; and as carboxylic acids with a valence of 4, pyromellitic acid, 1,2,3,4-cyclopentane tetracarboxylic acid and the like can be enumerated. Moreover, as polycarboxylic acid esters, those with a valence of 2 include dimethyl succinate, diethyl succinate, dibutyl oxalate, dimethyl malonate, dimethyl adipate, dimethyl maleate, and diethyl fumarate, those with a valence of 3 include tributyl citrate, 1,1,2-ethane tricarboxylic acid triethyle, and the like, and those with a valence of 4 include 1,1,2,2-ethane tetracarboxylic acid tetraethyl, 1,2,4-benzen tricarboxylic acid trimethyl, and the like.

In the precursor composition, the carboxylic acid ester with a valence of 2 may be at least one kind selected from ester succinate, ester maleate, and ester malonate. As concrete examples of these esters, dimethyl succinate, dimethyl maleate, and dimethyl malonate can be enumerated.

The polycarboxylic acid or the polycarboxylic acid ester may have a boiling point higher than that of the organic solvent. When the polycarboxylic acid or the polycarboxylic acid ester has a boiling point higher than that of the organic solvent, the reaction of the raw material composition can be quickly advanced.

The molecular weight of the polycarboxylic acid ester may be 150 or less. When the molecular weight of polycarboxylic acid ester is too large, the film might be damaged easily when ester volatilizes at the time of heat-treatment, and a dense film may not be obtained.

The polycarboxylic acid ester may preferably be in a liquid state at room temperature. This is because the liquid might gel if polycarboxylic acid ester is in a solid state at room temperature.

The complex metal oxide that is obtained by the precursor composition described above, which may be expressed by Pb(Zr, Ti)₁₋ₓNbₓO₃ (PZTN), may contain Nb in a range of 0.05≦x≦1, and more preferably in a range of 0.1≦x≦0.3. Also, the complex metal oxide described above may preferably include Si, or Si and Ge in 0.5 mol % or more, and more preferably in 0.5 mol % or more but less than 5 mol %. In accordance with the present embodiment, the complex metal oxide may be Pb(Zr, Ti, Nb) O₃ (PZTN) in which Nb is doped in the Ti site.

Because the PZTN composing the ferroelectric layer in accordance with the present embodiment includes Nb in the specific proportion, adverse effects by the lead vacancy are canceled, and excellent composition controllability can be obtained.

The amount of polycarboxylic acid or polycarboxylic acid ester to be used depends on the composition of the complex metal oxide. For example, the total molar ion concentration of the metals for forming the complex metal oxide and the molar ion concentration of polycarboxylic acid (ester) may preferably be in a ratio of 1≧(molar ion concentration of polycarboxylic acid (ester))/(total molar ion concentration of the metals of the raw material solution).

It is noted that the number of moles of the polycarboxylic acid or polycarboxylic acid ester refers to its valence. In other words, in the case of polycarboxylic acid or polycarboxylic acid ester with a valence of 2, one polycarboxylic acid or polycarboxylic acid ester molecule can be bonded with two raw material molecules. Therefore, the ratio is 1:1 when the amount of polycarboxylic acid or polycarboxylic acid ester is 0.5 mol for one mol of the metals of the raw material solution.

The ferroelectric layer 36 may be obtained through coating the precursor composition described above on the first electrode 34, and applying a heat treatment to the coated precursor composition.

Concretely, the precursor composition is coated on a base substrate by, for example, a spin coat method, and a drying treatment is conducted at 150-180° C., using a hot plate to remove the solvent. Then, a cleaning thermal treatment is conducted using a hot-plate at 300-350° C. (mainly to decompose and remove organic compositions). Then, the aforementioned coating step, drying treatment step, and cleaning thermal treatment are conducted multiple times according to the requirement to thereby obtain a coated film having a desired film thickness. Further, the ferroelectric layer 36 having a desired film thickness is formed by crystallization annealing (sintering). The sintering for crystallization may be conducted by using rapid thermal annealing (RTA) in an oxygen atmosphere at 650° C.-700° C.

Furthermore, a second interlayer dielectric layer 40 that covers the ferroelectric capacitor 30 is formed, and then second contact sections 42 are formed. The second interlayer dielectric layer 40 and the second contact sections 42 may be formed by a forming method similar to the forming method used for forming the first interlayer dielectric layer 16 and the first contact sections 18.

(3) A first wiring layer 43 is formed on the second interlayer dielectric layer 40 by a known method. A conductive lower electrode barrier layer 44, a conductive layer 46 and an upper electrode barrier layer 48 that compose the first wiring layer 43 may be formed by successively forming layers for forming the aforementioned layers, and then patterning the layers by known lithography and etching methods. Then, a third interlayer dielectric layer 50 and third contact sections 52 are formed. The third interlayer dielectric layer 50 and the third contact sections 52 may be formed by a forming method similar to the forming method used for forming the first interlayer dielectric layer 16 and the first contact sections 18.

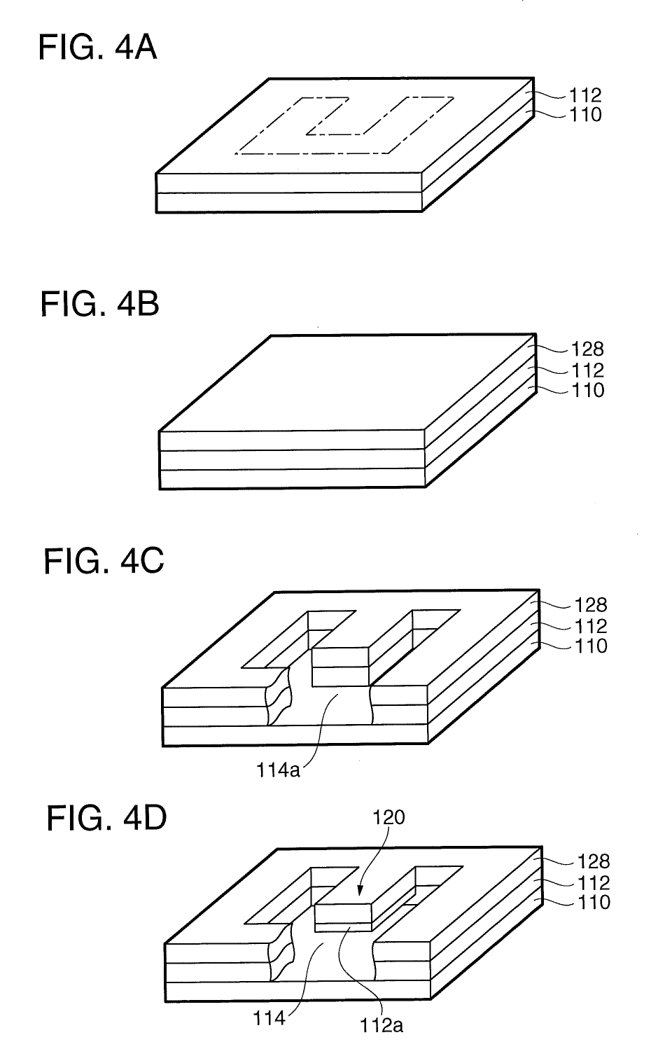

(4) Next, a method for manufacturing a pressure sensor 100 is described with reference to FIG. 3 and FIGS. 4A-4D. In FIG. 4C and FIG. 4D, a second dielectric layer 112 and a piezoelectric laminate section 128 are shown in a partially broken view.

First, as shown in FIG. 3 and FIG. 4, a first dielectric layer 110 is formed on the fourth interlayer dielectric layer 60 (see FIG. 1). The first dielectric layer 110 may be composed of, for example, alumina. The first dielectric layer 110 may be formed by a CVD method. A second dielectric layer 112 composed of, for example, silicon oxide is formed on the first dielectric layer 110.

Then, referring to FIG. 4A, an impurity, such as, for example, boron is doped in an area other than a region indicated by a broken line (a region where a cavity 114 is to be formed). A mask of a resist layer may be formed in advance in the region indicated by the broken line, such that boron is not doped in the region. The other area where boron is doped has a smaller etching rate to an etchant.

Then, as shown in FIG. 4B, a first conductive layer 122, a piezoelectric layer 124 and a second conductive layer 126 are successively formed on the second dielectric layer 112, thereby forming a piezoelectric laminate section 128. As the piezoelectric layer 124, a complex oxide of a kind similar to that of the ferroelectric layer 36 of the ferroelectric capacitor 30 may be used, and for example, the aforementioned PZTN may be used. The PZTN layer may be formed by a method similar to the film forming method applied for forming the ferroelectric layer 36 described above.

Then, as shown in FIG. 4C, the piezoelectric laminate section 128 is patterned by known lithography and etching methods, whereby an opening section for the cavity 114 is formed. Furthermore, the second dielectric layer 112 is etched by using, for example, a mixed solution of ethylenediamine and pyrocatechol, thereby forming a groove 114a. In this instance, the first dielectric layer 110 functions as an etching stopper.

When the etching is further continued, the second dielectric layer 112 located at a lower section of the piezoelectric laminate section 128 is etched, whereby a cantilever-like oscillator 120 is formed, as shown in FIG. 4D. In this instance, the etching may preferably be conducted in a manner that a portion of the second dielectric layer 112 remains.

Although not shown, the manufacturing process may include the step of connecting the pressure sensor 100 with the wiring layer of the FeRAM portion or devices such as the MOS transistor through the contact sections.

By the process described above, a semiconductor device 1000 having the pressure sensor 100 shown in FIG. 1 is manufactured.

### 2. Second Embodiment

2.1. Semiconductor Device Having Pyroelectric Sensor

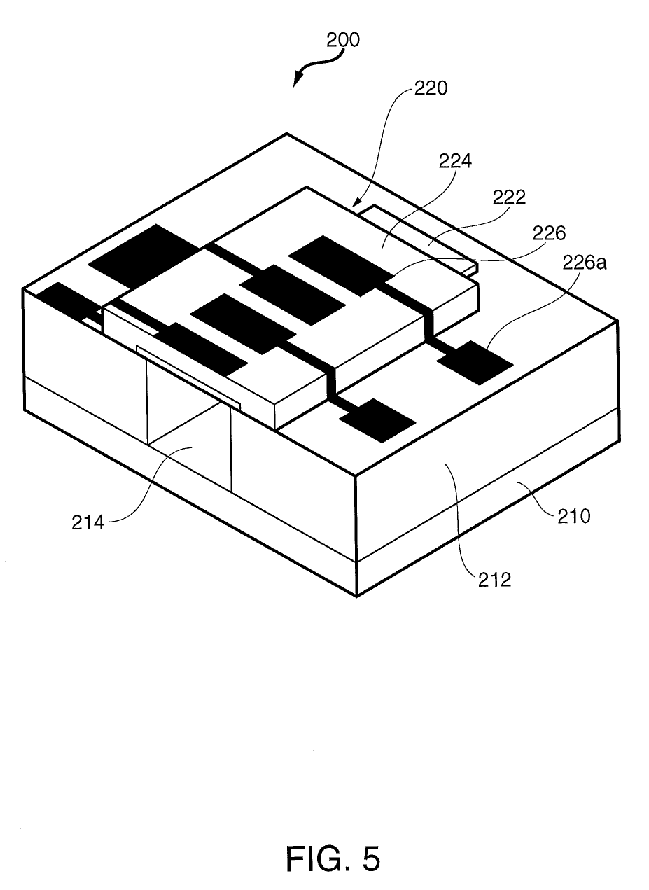

A semiconductor device in accordance with the present embodiment has a pyroelectric sensor as a sensor. The pyroelectric sensor is formed on the memory section 1000F composing the FeRAM shown in FIG. 1. FIG. 5 is a schematic perspective view of a pyroelectric sensor 200, and a part thereof is cut out so that its interior can be seen. The memory section 1000F is the same as the example shown in FIG. 1, and the pyroelectric sensor 200 is described below.

In accordance with the present embodiment, the pyroelectric sensor 200 is formed at the uppermost layer (on the fourth interlayer dielectric layer 60) of the semiconductor device 1000. The pyroelectric sensor 200 obtains an electrical output by heat, and includes an infrared sensor. Although not shown in the figure, the pyroelectric sensors 200 may be arranged in a plurality of rows, which may be formed in an array.

The pyroelectric sensor 200 includes, as shown in FIG. 5, a first dielectric layer 210 formed on the fourth interlayer dielectric layer 60 of the memory section 1000F shown in FIG. 1, and a second dielectric layer 212 formed on the first dielectric layer 210. On the second dielectric layer 212 is formed a pyroelectric laminate section 220 in which a first electrode layer 222, a pyroelectric layer 224 and a second electrode layer 226 are laminated. A cavity 214 is formed in the second dielectric layer 212.

The first dielectric layer 210 may be composed of, for example, alumina. As the material of the second dielectric layer 212, for example, silicon oxide may be used. The first electrode layer 222 may be formed from a metal such as ruthenium, iridium and platinum, or a conductive oxide such as iridium oxide. As the material of the pyroelectric layer 224, a complex oxide of a kind similar to that of the ferroelectric layer 36 of the ferroelectric capacitor 30 may preferably be used without any particular limitation. For example, when PZTN is used as the ferroelectric layer 36, PZTN may also be used as the pyroelectric layer 224. However, the ratio between zirconium (Zr), titanium (Ti) and niobium (Nb) is appropriately selected in consideration of the characteristics of the ferroelectric or pyroelectric material. The composition ratio (mol ratio) of PZTN composing the pyroelectric layer 224 may be, for example, Pb/Zr/Ti/Nb=115/15/70/15.

Although not shown in the figure, the pyroelectric sensor 200 and the wiring layer and devices such as the MOS transistor of the memory section 1000F which compose the FeRAM are connected to one another through the contact sections.

According to the semiconductor device 1000 described above, the pyroelectric sensor 200 is formed in a manner being laminated above an area where the ferroelectric capacitor 30 is formed, such that the pyroelectric sensor 200 and the ferroelectric capacitor 30 can be formed compactly in a specified region. As a result, the routing distance of the wiring can be made shorter, compared to the case where the pyroelectric sensor is not laminated, such that a signal from the pyroelectric sensor 200 can be effectively stored in the ferroelectric capacitor 30. The longer the routing length of the wiring becomes, the greater noises become. Therefore, in order to securely pick up a weak signal from the pyroelectric sensor 200, a certain measure to amplify the signal near the pyroelectric sensor or the like may need to be provided. However, in accordance with the present embodiment, because the pyroelectric sensor 200 and the ferroelectric capacitor 30 composing the FeRAM can be formed close to each other, such an amplification device is not required, and a simpler circuit structure can be used.

Also, by forming the ferroelectric layer 36 of the ferroelectric capacitor 30 and the pyroelectric layer 224 of the pyroelectric sensor 200 with the same kind of complex oxide, the process efficiency is improved.

The pyroelectric sensor 200 shown in FIG. 5 is an example of pyroelectric sensors, and can be in a variety of known configurations as a pyroelectric sensor.

2.2. Method for Manufacturing Semiconductor Device Having Pyroelectric Sensor

(1) The memory section 1000F composing the FeRAM may be formed by a method similar to the method described in the first embodiment, and therefore its detailed description is omitted. An example of a method for manufacturing the pyroelectric sensor 200 is described below with reference to FIG. 5.

First, as shown in FIG. 5, a first dielectric layer 210 is formed on the fourth interlayer dielectric layer 60 (see FIG. 1). As the first dielectric layer 210, for example, alumina can be used. The first dielectric layer 210 may be formed by a CVD method. A second dielectric layer 212 composed of, for example, silicon oxide is formed on the first dielectric layer 210. A first electrode layer 222 is formed on the second dielectric layer 212. The first electrode layer 222 is patterned by known lithography and etching methods. Then, while a resist layer is left remained on the first electrode layer 222, an impurity, such as, for example, boron is doped in areas other than an area where a cavity 214 is to be formed. Boron is not doped in the area that is masked by the resist layer. The area where boron is doped has a smaller etching rate to an etchant. Then, for example, an opening section for injecting an etchant is formed in the first electrode layer 222, and an etchant is injected through the opening section, whereby a cavity 214 is formed in an area where boron is not doped. As the etchant, a mixed solution of ethylenediamine and pyrocatechol may be used. In this instance, the first dielectric layer 210 functions as an etching stopper.

Then, a pyroelectric layer 224 is formed on the second dielectric layer 212 and the first electrode layer 222. The pyroelectric layer 224 is formed through forming a pyroelectric layer, and patterning the layer by known lithography and etching methods. As the pyroelectric layer 224, a complex oxide of a kind similar to that of the ferroelectric layer 36 of the ferroelectric capacitor 30 may be used. For example, the above-described PZTN may be used. The PZTN layer may be formed by a film forming method similar to the film forming method used for forming the ferroelectric layer described above.

Then, a second electrode layer 226 is formed on the pyroelectric layer 224. The second electrode layer 226 is connected to a pad 226a on the second dielectric layer 212. As the material of the second electrode layer 226, Ni—Cr alloy may be used.

Although not shown in the figure, the manufacturing method may include the step of connecting the pyroelectric sensor 200 through the contact sections with the wiring layer and devices such as the MOS transistor which compose the memory section 1000F composing the FeRAM (see FIG. 1).

By the process described above, the semiconductor device 1000 having the pyroelectric sensor 200 shown in FIG. 5 is manufactured.

### 3. Third Embodiment

3.1. Semiconductor Device Having Magnetic Sensor

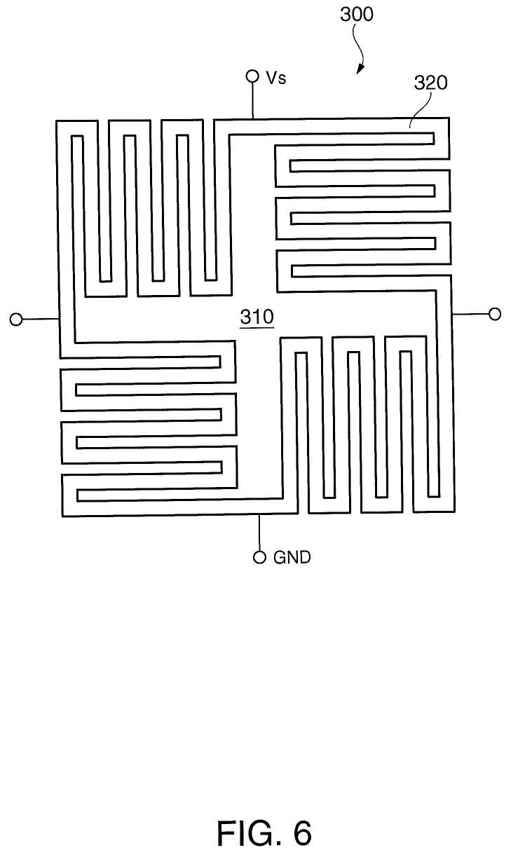

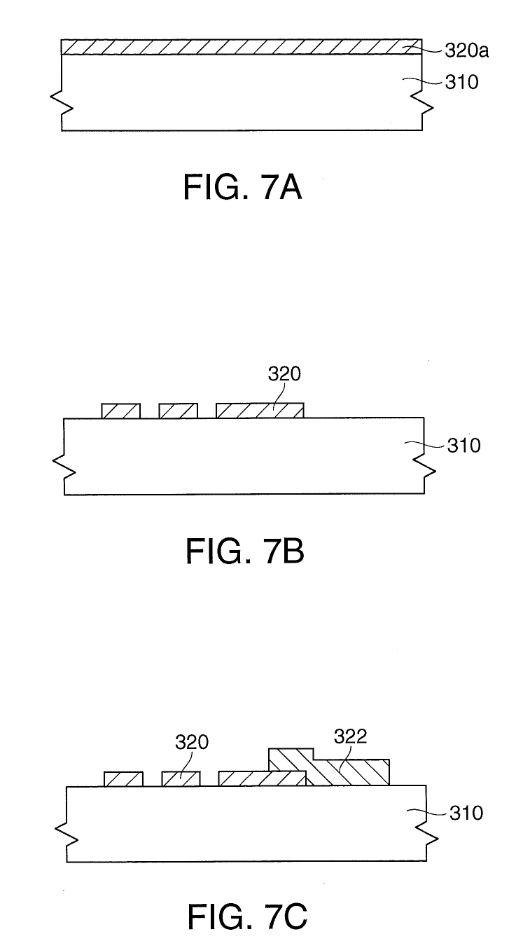

In accordance with the present embodiment, a semiconductor device has a magnetic sensor (MR sensor) as a sensor. The magnetic sensor is formed on the memory section 1000F composing the FeRAM shown in FIG. 1. FIG. 6 is a plane view schematically showing a magnetic sensor 300. FIGS. 7A through 7C are cross-sectional views schematically showing a method for manufacturing the magnetic sensor 300. The memory section 1000F is the same as the example shown in FIG. 1, and the magnetic sensor 300 is described below.

In accordance with the present embodiment, the magnetic sensor 300 is formed at the uppermost layer (on the fourth interlayer dielectric layer 60) of the semiconductor device 1000, like the first embodiment. The magnetic sensor 300 is a magnetic conversion device using the anomalous magnetoresistance effect of ferromagnetic metal, which obtains an electrical output according to a change in the magnetic field. The magnetic sensor may be applied to contactless position detectors, contactless rotation detectors and the like. Although not shown in the figure, the magnetic sensor 300 may be arranged in a plurality of rows, which may be formed in an array.

The magnetic sensor 300 includes, as shown in FIGS. 6 and 7A-7C, a dielectric layer 310 formed on the fourth interlayer dielectric layer 60 of the memory section 1000F shown in FIG. 1, and a ferromagnetic magnetoresistance layer 320. The example shown in FIG. 6 is a full bridge type magnetic sensor 300. As the material of the ferromagnetic magnetoresistance layer 320, for example, Ni—Co alloy, Ni—Fe alloy or the like can be used.

Although not shown in the figure, the magnetic sensor 300 and the wiring layer and devices such as the MOS transistor which compose the memory section 1000F composing the FeRAM are connected to one another through the contact sections.

According to the semiconductor device 1000 described above, the magnetic sensor 300 is formed in a manner being laminated above an area where the ferroelectric capacitor 30 is formed, such that the magnetic sensor 300 and the ferroelectric capacitor 30 can be formed compactly in a specified region. As a result, the routing distance of the wiring can be made shorter, compared to the case where the pressure sensor is not laminated, such that a signal from the magnetic sensor 300 can be effectively stored in the ferroelectric capacitor 30. The longer the routing length of the wiring becomes, the greater noises become. Therefore, in order to securely pick up a weak signal from the magnetic sensor 300, a certain measure to amplify the signal near the magnetic sensor or the like may need to be provided. However, in accordance with the present embodiment, because the magnetic sensor 300 and the ferroelectric capacitor 30 composing the FeRAM can be formed close to each other, such an amplification device is not required, and a simpler circuit structure can be used.

Also, the ferroelectric capacitor 30 composing the FeRAM is difficult to be influenced by magnetic, such that it would be difficult for the magnetic sensor 300 to influence the ferroelectric capacitor 30 even when the magnetic sensor 300 is formed above the ferroelectric capacitor 30. Furthermore, because data from the sensor needs to be stored instantaneously, a FeRAM whose writing rate is greater than that of an EEPROM may preferably be used.

The magnetic sensor 300 shown in FIG. 6 is an example of magnetic sensors, and may be in a variety of known configurations as a magnetic sensor.

3.2. Method for Manufacturing Semiconductor Device Having Magnetic Sensor

(1) The memory section 1000F composing the FeRAM may be formed by a method similar to the method described in the first embodiment, and therefore its detailed description is omitted. A method for manufacturing the magnetic sensor 300 is described below with reference to FIGS. 7A-7C.

First, as shown in FIG. 7A, a dielectric layer 310 is formed on the fourth interlayer dielectric layer 60 (see FIG. 1). The dielectric layer 310 may be composed of, for example, silicon oxide. The dielectric layer 310 may be formed by a CVD method. When the dielectric layer 310 is formed from a silicon oxide layer, the dielectric layer 310 may be formed directly on the fourth interlayer dielectric layer 60.

Then, a ferromagnetic magnetoresistance layer 320 is formed on the dielectric layer 310. The ferromagnetic magnetoresistance layer 320 may be formed through forming a ferromagnetic magnetoresistance layer 320a, and then patterning the layer 320a by known lithography and etching methods, as shown in FIG. 7B. Then, a lead-out electrode layer 322 composed of, for example, aluminum is formed on the ferromagnetic magnetoresistance layer 320.

Although not shown in the figure, the manufacturing method may include the step of connecting the magnetic sensor 300 through the contact sections with the wiring layer and devices such as the MOS transistor which compose the memory section 1000F composing the FeRAM (see FIG. 1).

By the process described above, the semiconductor device 1000 having the magnetic sensor 300 shown in FIG. 6 is manufactured.

The invention is not limited to the embodiments described above, and many modifications can be made. For example, the invention may include compositions that are substantially the same as the compositions described in the embodiments (for example, a composition with the same function, method and result, or a composition with the same objects and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. A semiconductor device comprising:
a semiconductor substrate;
a transistor formed on the semiconductor substrate;
an interlayer dielectric layer that covers the transistor;
a ferroelectric capacitor formed above the interlayer dielectric layer and having a first electrode, a ferroelectric layer and a second electrode;
another interlayer dielectric layer that covers the ferroelectric capacitor and is different from the interlayer dielectric layer; and
a sensor that is formed above the semiconductor substrate, the sensor being one of a pressure sensor, a pyroelectric sensor and a magnetic sensor.

2. A semiconductor device according to claim 1, wherein the sensor is formed above the other interlayer dielectric layer.

3. A semiconductor device according to claim 1, wherein the sensor is formed on the semiconductor substrate.

4. A semiconductor device according to claim 1, wherein the ferroelectric capacitor and the sensor have layers composed of identical types of complex oxides.

5. A semiconductor device according to claim 1, wherein the ferroelectric layer of the ferroelectric capacitor is composed of a complex oxide expressed by Pb(Zr, Ti)₁₋ₓNbₓO₃.

6. A semiconductor device according to claim 5, wherein, in the complex oxide of the ferroelectric layer, x is in a range of 0.05≦x≦0.3.

7. A semiconductor device according to claim 5, wherein the complex oxide includes one of Si, and Si and Ge in 0.5 mol % or more.

8. A semiconductor device according to claim 1, wherein the sensor is a pressure sensor, and the pressure sensor has a ferroelectric layer.

9. A semiconductor device according to claim 1, wherein the sensor is a pyroelectric sensor, and the pyroelectric sensor has a ferroelectric layer.

10. A semiconductor device according to claim 8, wherein the ferroelectric layer is composed of a complex oxide expressed by Pb(Zr, Ti)₁₋ₓNbₓO₃.
